(19) United States
(12) Patent Application Publication
(10) Pub. No.: US 2009/0278121 A1
(43) Pub. Date: Nov. 12, 2009

(54) SYSTEM FOR DISPLAYING IMAGES AND FABRICATION METHOD THEREOF

(75) Inventors: Ramesh Kakkad, Gujarat (IN); Keiichi Sano, Taipei City (TW); Fu-Yuan Hsueh, Bade City (TW); Chih-Chung Liu, Hsinchu City (TW); Sheng-Wen Chang, Yangmei Township (TW)

Correspondence Address: LIU & LIU, 444 S. FLOWER STREET, SUITE 1750, LOS ANGELES, CA, 90071, US

(73) Assignee: TPO Displays Corp., Chu-Nan (TW)

(21) Appl. No.: 12/427,142

(22) Filed: Apr. 21, 2009

Related U.S. Application Data
(63) Continuation of application No. 61/127,068, filed on May 8, 2008.

(51) Int. Cl. H01L 33/00; H01L 31/0376; H01L 29/786

(52) U.S. Cl. 257/43; 257/53; 438/24; 257/72; 257/E33.044; 257/E31.048; 257/E29.273; 257/E33.004; 257/E33.003; 257/E33.013

(57) ABSTRACT

A system for displaying images includes a thin film transistor array substrate including a substrate with thin film transistors array and at least one light-sensing element containing an amorphous silicon layer formed on the substrate, wherein the light-sensing element has a current flow direction perpendicular to the substrate.

### CROSS REFERENCE TO RELATED APPLICATIONS

This application claims the benefit of U.S. Provisional Application No. 61/127,068, filed May 8, 2008, the entirety of which is/are incorporated by reference herein.

### BACKGROUND OF THE INVENTION

1. Field of the Invention

The present invention relates to a system for display images including thin film transistor liquid crystal displays (TFT-LCDs), and more particularly relates to a TFT array substrate comprising at least one light-sensing element containing an amorphous silicon layer and a fabrication method thereof.

2. Description of the Related Art

A liquid crystal display (LCD) device typically comprises a lower substrate, an upper substrate and a liquid crystal layer interposed therebetween. The upper substrate typically comprises a color filter and a common electrode. The lower substrate is the well-known thin film transistor (TFT) array substrate. In order to support additional functions such as ambient light sensing, touch sensing, and image sensing in the LCD display device, a light-sensing element is provided in the TFT array substrate in the display device.

FIG. 1 shows a TFT array substrate 10 used in a conventional LCD device incorporating light-sensing elements. The TFT array substrate 10 includes a transparent substrate 12 with an optional buffer layer 14 formed thereon. A driver area 40 and a pixel area 50 are defined over the TFT array substrate 10. An n-type TFT 60, a p-type TFT 70 and a light-sensing device 80 are provided in the driver area 40 of the TFT array substrate 10, and an n-type TFT 85 and a storage capacitor 90 are provided in a pixel area 50 of the TFT array substrate 10.

The light-sensing device 80 in the driver area 40 is formed with a laterally connected p-doped region 16D, an undoped region 16A, an n-doped region 16C, and another n-doped region 16B, thereby functioning as a PIN⁻N photodiode. Conductive contacts 24 are provided and formed through the interlayer dielectric layer 20 and the gate dielectric layer 18, physically contacting the p-doped region 16D and the n-doped region 16B, respectively. The transparent conductor layer 30 over the inter-layer dielectric 20 in the light-sensing device 80 acts as a gate electrode to modulate the current through the PNN⁻N. This transparent conductor layer also allows the ambient light to reach the PNN⁻N sensing element. The light-sensing device 80 provides functions such as ambient light sensing, touch sensing, and image sensing for the display device.

Although FIG. 1 shows the light-sensing device 80 placed in the driver region 40, it can be either in the driver region 40 or in the pixel region 50 depending upon its specific function. For function such as power saving, the light-sensing elements would be placed in a driver region, while for functions such as image sensing or optical touch sensing, an array of light sensing elements would be placed in pixel areas. The light-sensing device 80 and the TFTs 60, 70, and 85 can be simultaneously fabricated in the TFT array substrate 10 used in a conventional display device incorporating light-sensing elements, nevertheless, it has some technological drawbacks. For example, when the light-sensing device 80 is placed in the pixel area for functions such as touch-sensing or image-sensing, it occupies some area in the pixel and reduces the pixel transmission area or the aperture ratio. Additionally, when the low temperature polysilicon (LTPS) layer is adopted for forming channel layers of the n-type TFTs 60 and 85, and the p-type TFT 70, the PIN⁻N light-sensing device 80 is also formed with the polysilicon layer. The photosensitivity of the polysilicon layer is quite poor and the sensitivity to ambient light is further reduced due to the presence of display backlight. The photosensitivity of amorphous silicon films is several orders of magnitude higher than polysilicon films, thus use of an amorphous silicon photo-sensing layer would be preferred. However, the degradation of photosensitivity with the usage time is a big problem for the amorphous silicon layer as descried below. Since the light-sensing device 80 is formed with a photodiode (or a photo-TFT), having a direction of current flow parallel to the transparent substrate 12, current density value is high because the current flows through a small cross-sectional area, which depend upon the thicknesses of the active layers used therein. The reliability problem is especially severe for a-Si TFT light sensing-elements, as silicon-hydrogen bonds in amorphous silicon break at even moderately high current densities leading to significant reduction in photosensitivity with the usage time.

What is needed, therefore, is a TFT array substrate incorporated with an improved light sensing structure for display devices. This light sensing structure must have high photosensitivity and high reliability and it should be formed without many additional process steps to the TFT array fabrication process.

### BRIEF SUMMARY OF THE INVENTION

In view of the previously described problems, various embodiments of systems for displaying images and fabrication methods thereof are proposed.

One embodiment of a system for displaying images comprises a thin film transistor array substrate comprising a substrate with thin film transistors array and at least one light-sensing element containing an amorphous silicon layer formed on the substrate, wherein the light-sensing element has a current flow direction perpendicular to the substrate.

An embodiment of a method for forming a system for displaying images comprises providing a substrate with a thin film transistor array. A bottom electrode is formed on the substrate. A light-sensing element containing an amorphous layer is formed on the bottom electrode. A top electrode is formed on the light-sensing element.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a conventional TFT array substrate of a display device;

FIGS. 2 through 5 are cross-sectional views of intermediate stages in the manufacturing of a TFT array substrate in accordance with an embodiment of the invention;

FIG. 6 shows a TFT array substrate in accordance with another embodiment of the invention;

FIG. 7 shows a TFT array substrate in accordance with yet another embodiment of the invention;

FIG. 8 shows a TFT array substrate in accordance with yet another embodiment of the invention;

FIG. 9 shows a TFT array substrate in accordance with yet another embodiment of the invention;

FIG. 10 shows a TFT array substrate in accordance with yet another embodiment of the invention;

FIG. 11 shows a TFT array substrate in accordance with yet another embodiment of the invention;

FIG. 12 shows a TFT array substrate in accordance with yet another embodiment of the invention;

FIG. 13 shows a TFT array substrate in accordance with yet another embodiment of the invention; and

FIG. 14 schematically shows a system for displaying images including the TFT array substrate according to an embodiment of the invention.

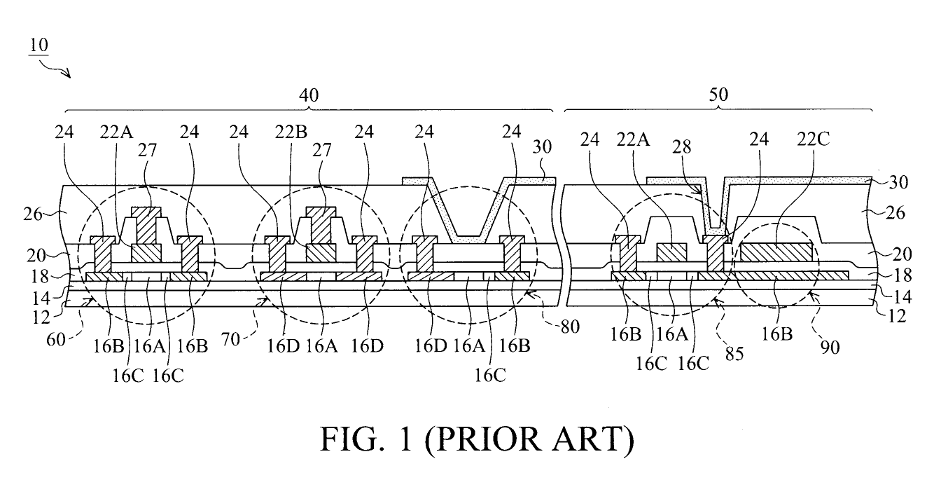

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

In this specification, expressions such as “overlying the substrate”, “above the layer”, or “on the film” simply denote a relative positional relationship with respect to the surface of a base layer, regardless of the existence of intermediate layers. Accordingly, these expressions may indicate not only the direct contact of layers, but also, a non-contact state of one or more laminated layers.

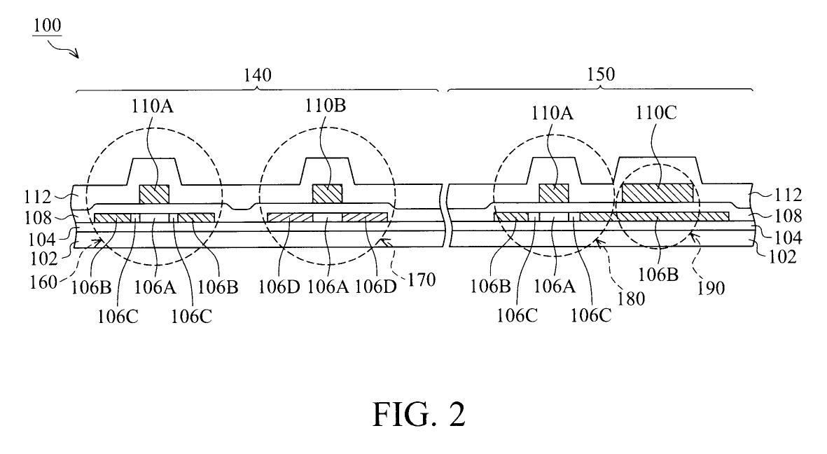

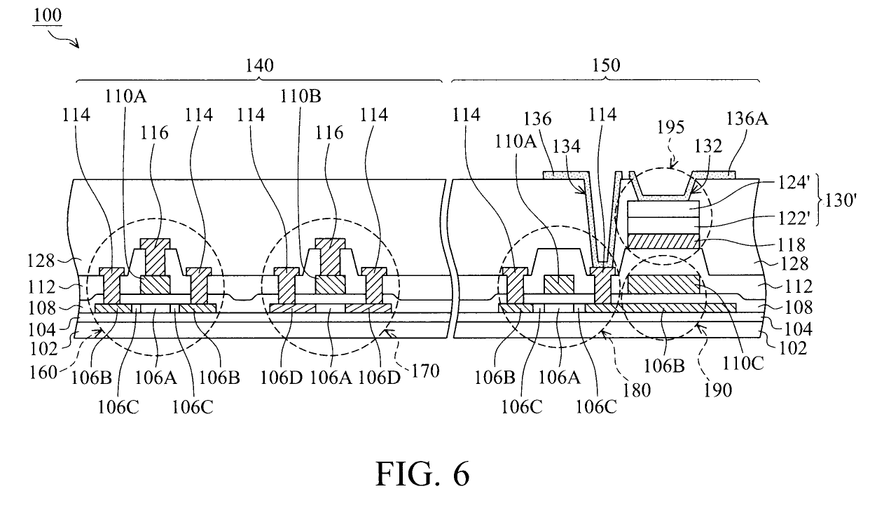

A novel method for forming a system for displaying images is provided. The system for displaying images has a thin film transistor (TFT) array substrate provided with at least one light-sensing element and the intermediate stages of manufacturing an exemplary TFT array substrate of the invention are illustrated in FIGS. 2 through 5. Variations of the embodiments of the TFT array substrate are then discussed in FIGS. 6-11. For simplicity, in these embodiments, only manufacturing of a few TFTs thereon are illustrated.

Referring to FIG. 2, a substantially fabricated TFT array substrate 100 comprising a driver area 140 and a pixel area 150 is provided, having a buffer layer 104 optionally formed on a transparent substrate 102. In general, the buffer layer 104 may comprise silicon oxide, silicon nitride or a combination thereof, and can be a stack of a silicon oxide layer and a silicon nitride layer and the transparent substrate 102 may comprises a transparent insulating material such as a glass, plastic, or ceramic substrate or a non-transparent substrate such as a metal or a metal alloy. A plastic substrate can comprise single or multiple layers of at least one of, for example, polyethylene terephthalate, polyester, polycarbonates, polyacrylates, or polystyrene.

As shown in FIG. 2, the TFT array substrate 100 is provided with a plurality electronic elements such as an n-type TFT 160 and a p-type TFT 170 in the driver area 140 of the TFT array substrate 100, and an n-type TFT 180 and a storage capacitor 190 in the pixel area 150 of the TFT array substrate 100. The above electronic elements are conformably covered by an interlayer dielectric layer 112 and suitable materials for the interlayer dielectric layer 112 can include insulating oxides, nitrides, or combinations thereof. Exemplary materials can include silicon nitride, and silicon oxide.

In FIG. 2, the n-type TFT 160 in the driver area 140 and the n-type TFT 180 formed in the pixel area 150 are both formed with an active layer comprising a pair of source/drain regions 106B comprising an n-type doped semiconductor layer, a channel region 106A of an intrinsic semiconductor layer formed between the source/drain regions 106B, lightly-doped source/drain regions 106C (LDD regions) comprising an n-type doped semiconductor layer formed between the channel region 106A and source/drain regions 106B, a gate insulating layer 108 such as a silicon oxide layer overlying the source/drain regions 106B and the channel region 106A and LDD regions 106C, and a gate electrode 110A overlying a portion of the gate insulating layer 108.

Moreover, the p-type TFT 170 in the driver area 140 is formed with an active layer comprising source/drain regions 106D comprising a p-type doped semiconductor layer, a channel region 106A of an intrinsic semiconductor layer formed between the source/drain regions 106D, a gate insulating layer 108 such as a silicon oxide layer overlying the source/drain regions 106D and the channel region 106A, and a gate electrode 110B overlying a portion of the gate insulating layer 108.

Further, the storage capacitor 190 provided in the pixel area 150 is formed with a first electrode comprising an n-type doped semiconductor layer which also formed as a part of the source/drain region 106B of the n-type TFT 180. The first electrode is covered by the gate insulating layer 108 and a second electrode 110C is formed over a portion of the first electrode and the portion of the gate insulating layer 108 therebetween may function as a storage region of the storage capacitor 190.

Fabrication of the electronic elements such as the n-type TFTs 160 and 180, the p-type TFT 170, and the storage capacitor 190 over the substrate 102 are well known and can be formed by conventional TFT and storage capacitor fabrication techniques and are not described here in greater detail, for simplicity. The active layer may comprise polysilicon, amorphous silicon, microcrystalline silicon, zinc oxide or metal oxide semiconductor.

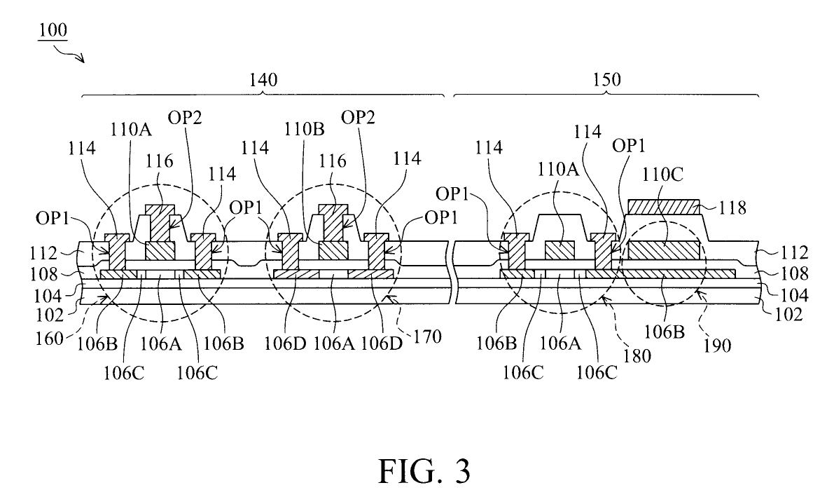

Next, in FIG. 3, a photoresist layer (not shown) with openings is formed and defined on the interlayer dielectric layer 112. The interlayer dielectric layer 112 is etched using the photoresist layer as a mask. A plurality of contact holes OP1 are thus formed to expose one of the source/drain regions 106B/106D in the driver area 140 and in the pixel area 150, and a plurality of contact holes OP2 are thus formed to expose one of the gate electrode 110A and 110B in the driver area 140 by etching the interlayer dielectric layer 112. The process of etching the interlayer dielectric layer 112 can include a wet etching or dry etching process. The photoresist layer is then removed after formation of the contact holes OP1 and OP2.

Next, a conductive layer (not shown) such as metal layer is formed over the interlayer dielectric layer 112, filling the contact holes OP1 and OP2. The conductive layer is then patterned by a conventional photolithography and etching process (not shown), thereby forming conductive members 114/116 including a plug portion formed in the contact holes OP1/OP2 and a line portion formed over a portion of the interlayer dielectric layer 112 adjacent to the contact holes OP1/OP2. A conductive member 118 is also formed over a portion of the interlayer dielectric layer 112 overlying the storage capacitor 190 in the pixel area 150.

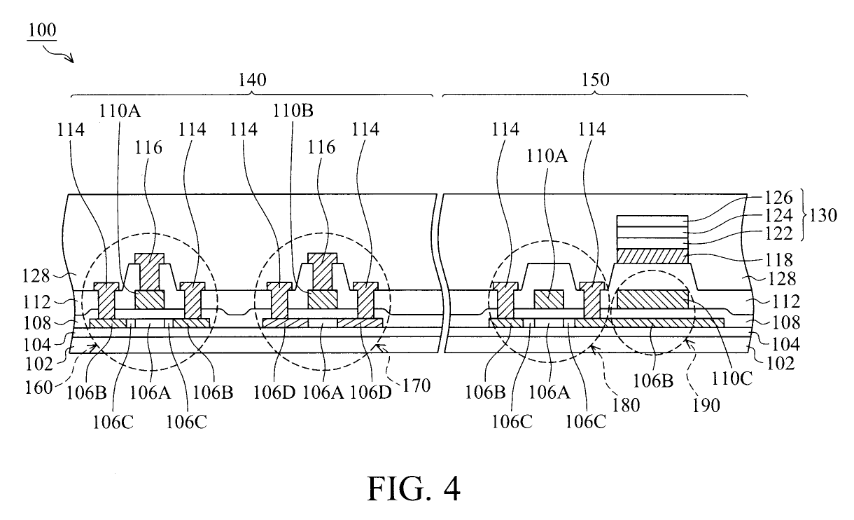

In FIG. 4, a light-sensing element 130 is formed over a portion of conductive member 118 in the pixel area 150. The light-sensing element 130 is illustrated as a three-layered composite structure including a first layer 122, a second layer 124 and a third layer 126 sequentially stacked over the conductive member 118. The first layer 122, the second layer 124 and the third layer 126 can be formed with a NIP or PIN structure, wherein N is an n-type silicon layer, I is an undoped amorphous silicon layer, and P is a p-type silicon layer. Fabrication of the first layer 122, the second layer 124 and the third layer 126 can be achieved by first performing sequential deposition of three silicon layers and selective etching for forming the light-sensing element 130. Doping of the first layer 122 and the third layer 126 can be in-situ achieved during deposition thereof or by an additional ion-implanting process incorporating suitable dopants performed after deposition thereof. After formation of the light-sensing element 130, a planarization or a passivation layer 128 of a material such as silicon nitride or a polyimide is formed over the TFT array substrate 110, covering the n-type TFTs 160 and 180, the p-type TFT 170, the storage capacitor 190, and the light-sensing element 130, thus providing the TFT array substrate 100 with a substantially planar surface.

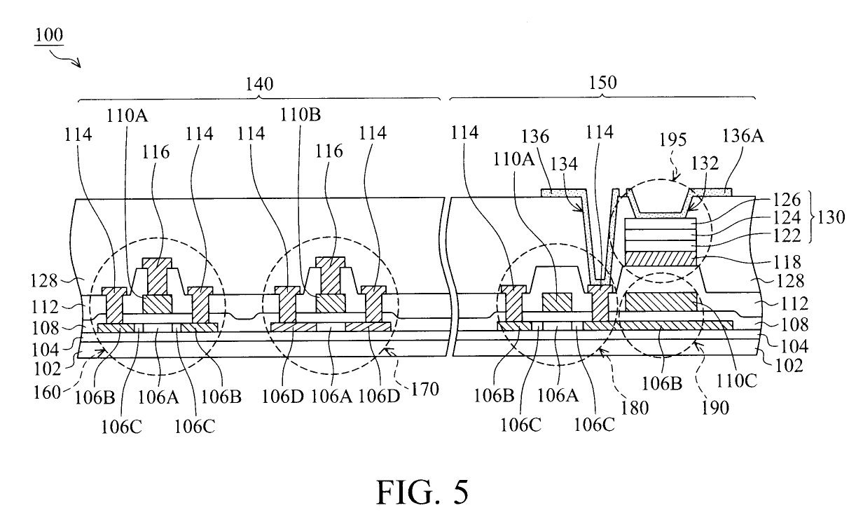

In FIG. 5, openings 132 and 134 are then formed in a portion of the planarization layer 128 in the pixel area, respectively exposing a portion of a top surface of the light-sensing element 130 and the conductive member 114 of the n-type TFT 180. A transparent conductive layer (not shown) is deposited and patterned to form a pixel electrode 136 and a top electrode 136A. The pixel electrode 136 and the top electrode 136A are conformably filled in each of the openings 132 and 134, respectively, thus physically contacting the conductive member 114 of the n-type TFT 180 exposed by thereof and the portion of the top surface of the light-sensing element 130, respectively. The transparent conductive layer can be indium tin oxide (ITO), indium zinc oxide (IZO), aluminum zinc oxide (AZO), or zinc oxide (ZnO) either singly or in combinations thereof. According to various embodiments, the transparent conductive layer can be formed by a process such as a sputtering, electron beam evaporation, thermal evaporation, or chemical vapor deposition process.

As shown in FIG. 5, the top electrode 136A overlying the light-sensing element 130 and the conductive member 118 (as a bottom electrode) forms a light-sensing device 195 for providing functions such as ambient light sensing, touch sensing, image sensing, power generation, and/or memory-in-pixel function of the display device.

The exemplary TFT array substrate 100 illustrated in FIG. 5 has several advantageous features. Since the light-sensing device 195 is provided in a region over the storage capacitor 190, an aperture ratio in the pixel area 150 is not reduced. Moreover, since the light-sensing device 195 is formed with a stacked layer structure, a current flow path therein is perpendicular to a surface of the TFT array substrate 100, thereby providing a more reliable light-sensing device 195 with reduced current density therein. Further, since the light-sensing element 130 of the light-sensing device 195 is formed with sub-layers of amorphous materials, sensitivity of the light-sensing element can be increased when compared to that using a light-sensing layer of polysilicon material and is not affected when formation of the TFTs 160, 170, and 180 therein adopt a Low Temperature Poly-Silicon (LTPS) process. Additionally, the light sensing element 130 is shielded from the display backlight by generally opaque electrode layers 118 and 110C, thus the light sensing signal from the light sensing layer measures mainly the ambient light intensity. This improves the accuracy of light sensing for functions such as touch sensing and ambient light sensing. For applications such as solar cell, it would be useful to make the electrodes 118 and 110C of a transparent material or alternatively thin enough to allow photons from back light to reach the light sensing element 130 to add power generation from the back-light. In other embodiments, the light sensing element may be formed in the pixel area at a place (not shown) other than overlying the storage capacitor area. In that case, the aperture ratio is affected, but others advantage mentioned above still remain.

FIG. 6 shows an alternative cross section of another exemplary TFT array substrate 100. In this embodiment, the light-sensing device 195 is formed with a two-layered light-sensing element 130′ including a stacked structure of a first layer 122′ and a second layer 124′ sequentially stacked over the conductive member 118. The first layer 122 and the second layer 124 can be formed with a stacked NI, IN, PI, or IP structure, wherein N is an n-type silicon layer, I is an undoped amorphous silicon layer, and P is a p-type silicon layer.

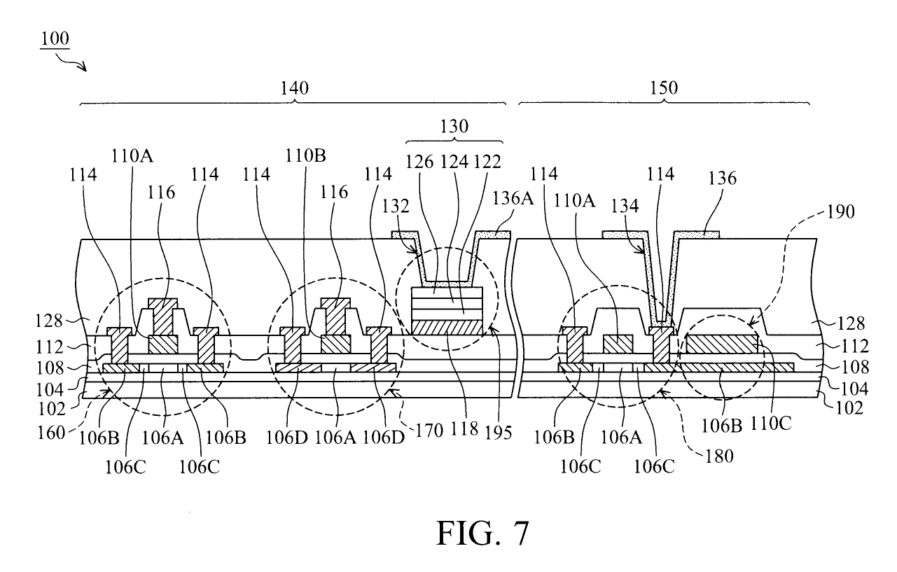

FIG. 7 shows an alternative cross section of yet another exemplary TFT array substrate 100. In this embodiment, the light-sensing device 195 is formed at a place in the driver area 140. The light-sensing device 195 is formed with a structure similar with that illustrated in FIG. 5 and is located over the interlayer dielectric layer 112.

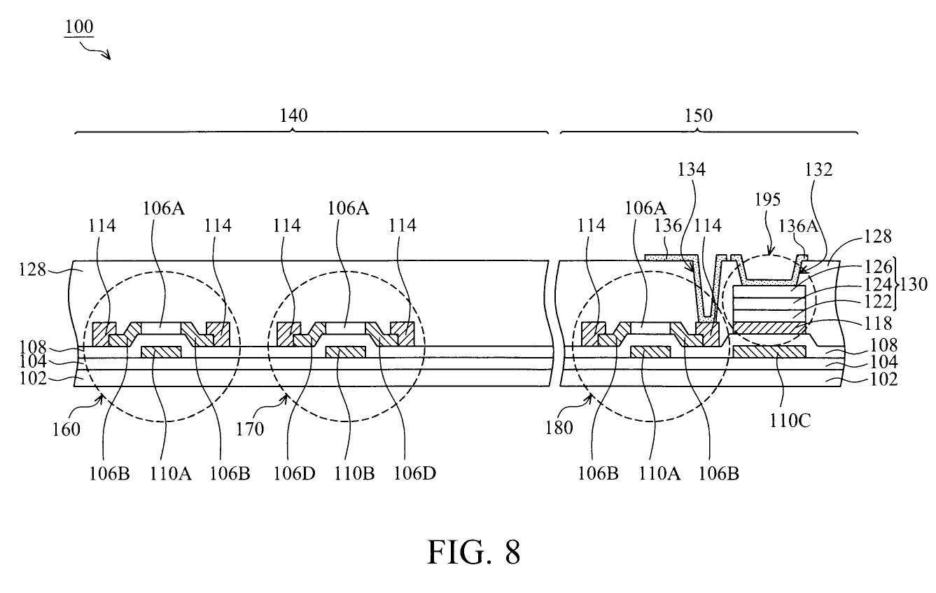

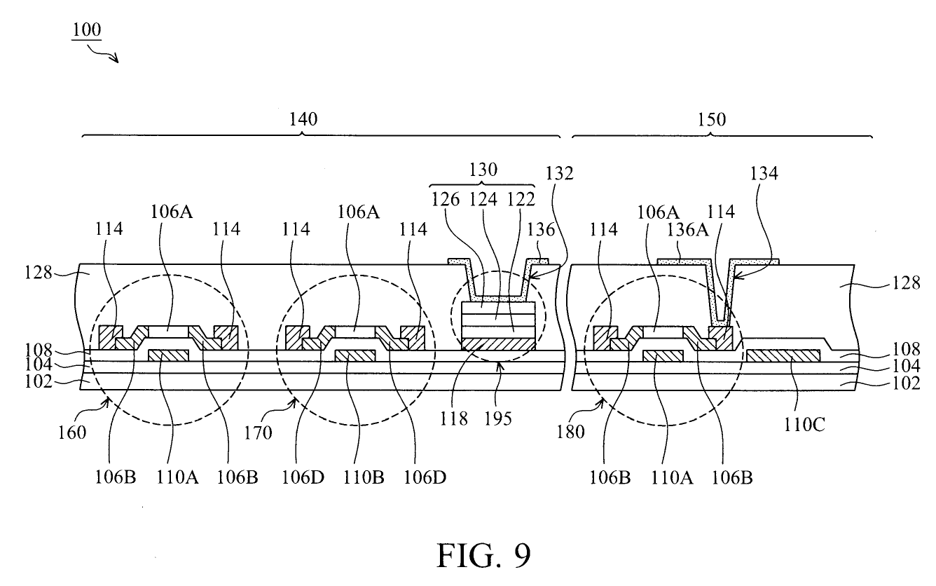

The TFTs shown in FIGS. 2-7 are all illustrated as TFTs in a top-gate formation, but are not limited thereto. The TFTs shown in FIGS. 2-7 can be partially or entirely replaced by the TFTs in a bottom-gate formation. FIGS. 8 and 9 show alternative cross sections of yet another exemplary TFT array substrate 100 similar with that illustrated in FIGS. 6 and 7, respectively. In these embodiments, the light-sensing device 195 is formed with a structure similar with that illustrated in FIGS. 6 and 7 and is located over the gate insulating layer 108. As shown in FIG. 8, an exemplary TFT array substrate having the light-sensing device 195 formed in the pixel area 150 is illustrated. The light-sensing device 195 can be also provided in the driver area 140, as shown in FIG. 9. Components of the TFTs 160. 170, and 180, and the light-sensing device 195 illustrated in FIGS. 8 and 9 are entitled with same reference numbers as that illustrated in FIGS. 6 and 7.

Fabrication of the TFT array substrate 100 having TFTs 160, 170, and 180 with a bottom gate structure illustrated in FIGS. 8 and 9 is described as follows:

A gate (e.g. the gate electrode 110A/110B/110C) of a thin film transistor (e.g. TFT 160/170/180) is formed over the substrate 102. A first dielectric layer (e.g. the gate insulating layer 108) is then formed on the gate. An active layer (e.g. the layer composed of the channel region 106A and 106B/106D) with a source/drain region (106B/106D) is formed on the first dielectric layer. A first conductive layer (not shown) is formed over the active layer and the first dielectric layer and is then patterned to form the bottom electrode (e.g. the bottom electrode 118) and a source/drain electrode (e.g. the source/drain electrode 114) contacting the source/drain region. A light sensing element (e.g. the light sensing element 130) is then formed over the bottom electrode. A second dielectric layer (e.g. the passivation layer 128) is then formed over the first dielectric layer and the light sensing element. A first opening (e.g. the opening 132) and a second opening (e.g. the opening 134) in the second dielectric layer, respectively exposing the source/drain electrode and the light-sensing element. A second conductive layer is formed over the second dielectric layer and in the first opening and the second opening and is then patterned to form the top electrode (e.g. the top electrode 136A) and a pixel electrode (the pixel electrode 136) contacting the source/drain electrode.

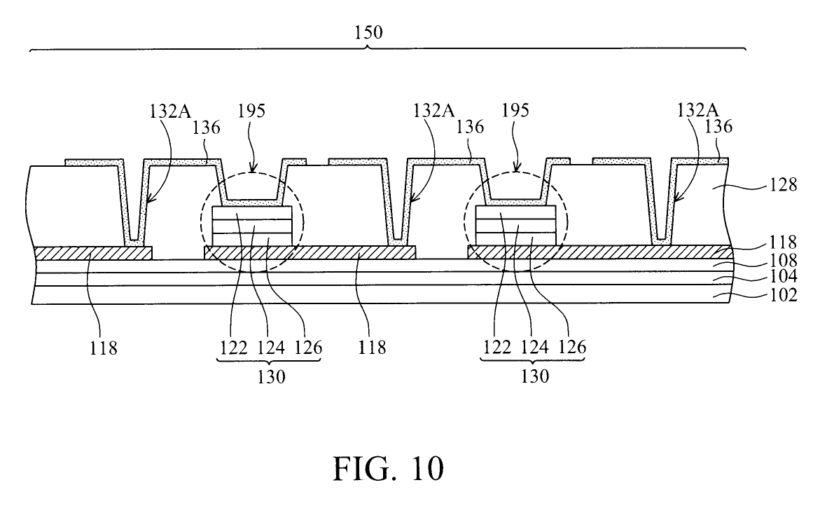

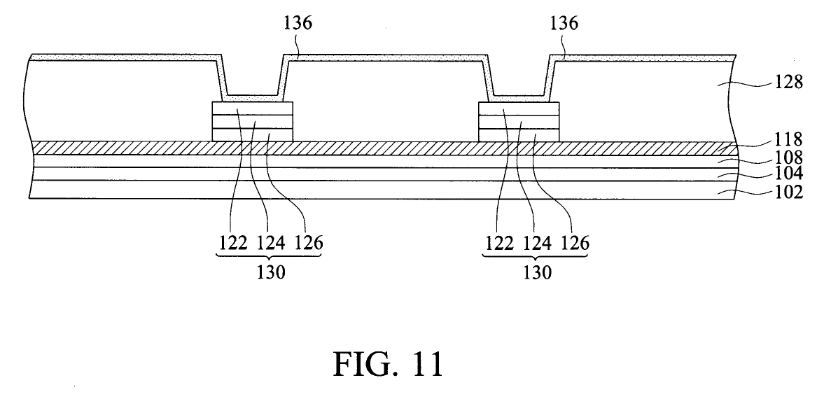

In other embodiments, it would be useful to form a plurality of light-sensing device 195 connected in series or in parallel over the TFT array substrate 100 at a suitable place in the pixel area 150 and/or the driver area 140. As shown in FIG. 10, a configuration showing two light-sensing devices 195 connected in series is illustrated. These two light-sensing devices 195 are now formed in the pixel area 150 with plurality of openings 132A formed in the passivation layer 128, thereby exposing a portion of the bottom electrode 118 of the light-sensing device 195, respectively. A plurality of top electrodes 136 are provided over the passivation layer 128 and contacted the bottom electrode 118 of a previous light-sensing device 195. These two light-sensing devices 195 shown in FIG. 10 can be also connected in parallel by respectively connecting their bottom electrodes and top electrodes as shown in the example in FIG. 11. For applications such as light sensing, touch sensing and ambient light sensing applications, the above shown light-sensing devices 195 connected in series can reduce dark currents thereof as the number of series connected light-sensing devices 195 increased, while photocurrent remained the same provided by individual light-sensing element therein, thereby improving photosensitivity thereof. For applications such as solar cell or memory in pixel application, the above shown light-sensing devices 195 connected in series also provide increased open circuit voltage as the number of series connected light-sensing devices 195 increased. The light sensing devices connected in parallel provide increased photocurrent, while open circuit voltage remain the same. The higher value of photocurrent of parallel-connected light sensing devices is useful for applications such as solar cell and light-sensing.

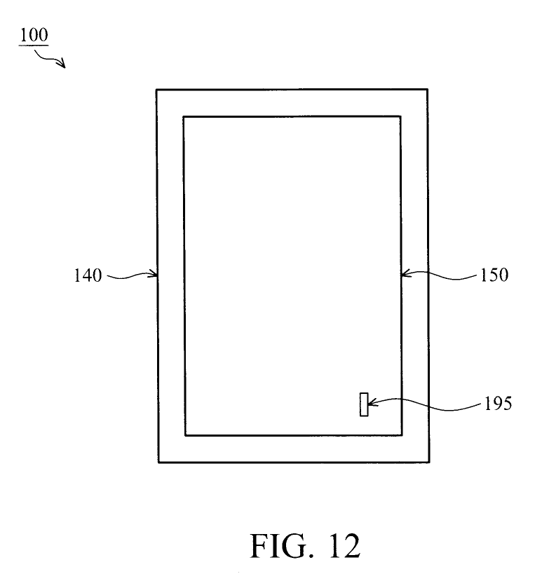

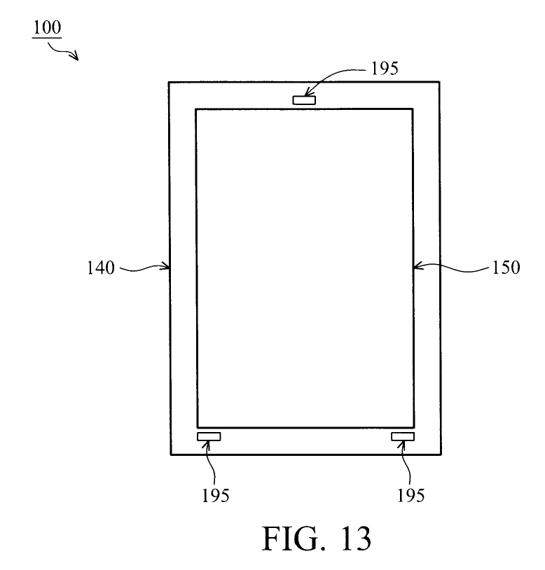

FIG. 12 is a schematic top view of the exemplary TFT array substrates 100 illustrated in FIGS. 5, 6 and 8, having the light-sensing device 195 provided in the pixel area 150. FIG. 13 is a schematic top view of the exemplary TFT array substrates 100 illustrated in FIGS. 7 and 9, having the light-sensing device 195 provided in the driver area 140. Similarly, one or more light-sensing device 195 can be provided over the TFT array substrates 100 illustrated in FIGS. 12 and 13, respectively.

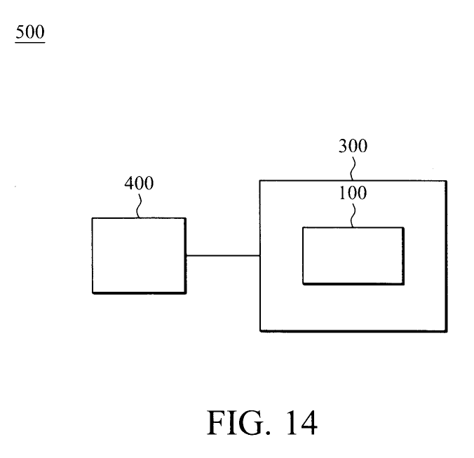

FIG. 14 schematically shows an embodiment of a system for displaying images which, in this case, is implemented as a display panel 300 or an electronic device 500. The display device can be incorporated into a display panel 300. As shown in FIG. 14, the display panel 300 comprises a TFT array substrate, such as the TFT array substrate 100 shown in FIGS. 5, 6, 7, 8, and 9. The display panel 300 is applicable in a variety of electronic devices (in this case, electronic device 500).

Generally, the electronic device 500 can comprise the display panel 300 and an input unit 400. Further, the input unit 400 is operatively coupled to the display panel 100 and provides input signals (e.g., an image signal) to the display panel 300 to generate images. The electronic device 500 can be a mobile phone, digital camera, personal digital assistant (PDA), notebook computer, desktop computer, television, car display, portable DVD player, global positioning system, digital photo frame or avionics display, for example.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images, comprising:
a thin film transistor array substrate, comprising:
a substrate with array of thin film transistors; and
at least one light-sensing element containing an amorphous silicon layer formed on the substrate, wherein the light-sensing element has a current flow direction perpendicular to the substrate.

2. The system for displaying images as claimed in claim 1, wherein the light-sensing element is formed with a stacked NI, IN, PI, IP, NIP or PIN structure, and wherein N is an n-type silicon layer, I is an undoped amorphous silicon layer, and P is a p-type silicon layer.

3. The system of displaying images as claimed in claim 1, further comprising a bottom electrode under the light sensing element and a top electrode above the light sensing element.

4. The system for displaying images as claimed in claim 3, wherein the top electrode comprises transparent conductive material(s).

5. The system for displaying images as claimed in claim 1, wherein the thin film transistor comprises an active layer of microcrystalline silicon, amorphous silicon, polysilicon, zinc oxide or a metal oxide semiconductor.

6. The system for displaying images as claimed in claim 1, wherein the thin film transistors have a top gate structure or a bottom gate structure.

7. The system for displaying images as claimed in claim 1, wherein the thin film transistor further comprising:
an active layer with a source/drain region formed on the substrate;
a gate insulating layer formed on the active layer;
a gate formed on the gate insulating layer;
a first dielectric layer formed on the gate;
a contact hole formed in the first dielectric layer and exposed the source/drain region; and
a source/drain electrode formed on the source/drain region through the contact hole, wherein the source/drain electrode and the bottom electrode both formed on the first dielectric layer.

8. The system for displaying images as claimed in claim 1, where the thin film transistor further comprising:
a gate formed on the substrate;
a gate insulating layer formed on the gate;
an active layer formed on the gate insulating layer; and
a source/drain electrode formed on the active layer, wherein the source/drain electrode and the bottom electrode both formed on the gate insulating layer

9. The system for displaying images as claimed in claim 1, wherein the substrate comprises a pixel area and a driver area, and the at least one light-sensing element is formed on the pixel area, the driver area or both of the pixel area and the driver area.

10. The system for displaying images as claimed in claim 9, further comprising a storage capacitor disposed in the pixel area, wherein the at least one light-sensing element is formed over the storage capacitor.

11. The system for displaying images as claimed in claim 1, further comprising a plurality of light-sensing elements, wherein the light-sensing elements are electrically connected in series.

12. The system for displaying images as claimed in claim 1, further comprising a plurality of light-sensing elements, wherein the light-sensing elements are electrically connected in parallel

13. The system for displaying images as claimed in claim 1, further comprising a display panel, wherein the thin film transistor array substrate forms a portion of the display panel.

14. The system for displaying images as claimed in claim 13, further comprising an electronic device, wherein the electronic device comprises:
the display panel; and
an input unit coupled to the display panel and operative to provide input to the display panel such that the display panel displays images.

15. The system for displaying images as claimed in claim 14, wherein the electronic device a mobile phone, digital camera, personal digital assistant (PDA), notebook computer, desktop computer, television, car display, portable DVD player, global positioning system, digital photo frame or avionics display.

16. A method of forming a system for displaying images, comprising:
providing a substrate with a thin film transistor array;
forming a bottom electrode on the substrate;
forming a light-sensing element containing an amorphous layer on the bottom electrode; and
forming a top electrode on the light-sensing element.

17. The method as claimed in claim 16, further comprising:
forming an active layer with a source/drain region on the substrate;
forming a gate insulating layer on the active layer;
forming a gate on the gate insulating layer; wherein the active layer, the gate insulating layer and the gate is formed a thin film transistor with a top gate structure
forming a dielectric layer on the thin film transistor;
forming a contact hole in the first dielectric layer and exposing a source/drain region of the thin film transistor;
forming a first conductive layer on the first dielectric layer and in the contact hole; and
patterning the conductive layer to form the bottom electrode and a source/drain electrode contacting the source/drain region.

18. The method as claimed in claim 16, further comprising:
forming a gate of a thin film transistor on the substrate;
forming a first dielectric layer on the gate;
forming an active layer with a source/drain region on the first dielectric layer;
forming a first conductive layer on the active layer and the first dielectric layer; and
patterning the conductive layer to form the bottom electrode and a source/drain electrode contacting the source/drain region.

19. The method as claimed in claim 18, further comprising:
forming a second dielectric layer on the first dielectric layer;
forming a first opening and a second opening in the second dielectric layer, exposing the source/drain electrode and the light-sensing element;
forming a second conductive layer on the second dielectric layer and in the second opening and the third opening; and
patterning the second conductive layer to form the top electrode and a pixel electrode contacting the source/drain electrode.
